(19) United States
(12) Patent Application Publication
(10) Pub. No.: US 2006/0054833 A1
(43) Pub. Date: Mar. 16, 2006

(54) Radiography system

(76) Inventors: Hisanori Tsuchino, Tokyo (JP); Yasuaki Tamakoshi, Tokyo (JP)

Correspondence Address: CANTOR COLBURN, LLP, 55 GRIFFIN ROAD SOUTH, BLOOMFIELD, CT, 06002, US

(21) Appl. No.: 11/226,552

(22) Filed: Sep. 14, 2005

(30) Foreign Application Priority Data
Sep. 16, 2004 (JP) 2004-269977

(51) Int. Cl. H01L 27/14

(52) U.S. Cl. 250/370.11

(57) ABSTRACT

A radiography system includes: a radiographic detector having a scintillator for receiving radiation transmitted through a subject to generate fluorescence, the radiographic detector to generate image information of the subject based on strength of the fluorescence generated by the scintillator; and a scintillator information adding-section to add scintillator type-related information related to a type of the scintillator, to the image information.

### BACKGROND OF THE INVENTION

1. Field of the Invention

The present invention relates to a radiography system.

2. Description of the Related Art

Conventionally, in the field of a radiographing for the purpose of medical diagnosis, a radiography system has been widely known in which a subject is subjected to radiation to detect the distribution of radiation rays transmitted through the subject, thereby obtaining a radiographic image of the subject. In the recent radiography systems, a radiographic detector of the so-called flat panel detector having a thin and flat panel-like shape in which a great number of photoelectric transducers are arranged in a matrix manner has been developed and used. In the radiographic detector, radiation rays transmitted through the subject are subjected to photoelectric conversion to provide an electronic signal as image information. The image information is subjected to image processing, thereby providing a radiographic image of the subject in an easy and prompt manner.

The above radiographic detector is mainly classified into the “direct conversion type” one for directly converting the radiation to an electronic signal and the “indirect conversion type” one for converting the radiation to fluorescence to convert the fluorescence to an electronic signal. An indirect conversion type radiographic detector generally includes a scintillator for receiving the radiation to generate fluorescence with the strength in accordance with the amount of the radiation (see Japanese Patent Laid-open Publication No. 7-140255 for example). Several types of such scintillators have been used. Japanese Patent Laid-open Publication No. 2001-37749 discloses a digital radiography system in which each radiographic detector is added with an ID so that each compensation table associated with the ID is used to compensate the image and also discloses a table in which each ID is associated with a fluorescent material type or the like.

### SUMMARY OF THE INVENTION

In accordance with one aspect of the present invention, a radiography system comprises:

a radiographic detector comprising a scintillator for receiving radiation transmitted through a subject to generate fluorescence, the radiographic detector to generate image information of the subject based on strength of the fluorescence generated by the scintillator; and

a scintillator information adding-section to add scintillator type-related information related to a type of the scintillator, to the image information.

In the specification, when the expression “A comprising (comprises) B and C” is used, “B” and “C” are not limited to independent members from each other. For example, one or more elements which are a part of “B” may function as one or more elements which are a part of “C”. Further, all elements constituting “B” may function as one or more elements which are a part of “C”. One or more elements which are a part of “B” may function as all elements constituting “C”. All elements constituting “B” may function as all elements constituting “C”.

### BRIEF DESCRIPTION OF THE DRAWINGS

The present invention will become more fully understood from the detailed description given hereinafter and the accompanying drawing given by way of illustration only, and thus are not intended as a definition of the limits of the present invention, and wherein:

FIG. 1 is a schematic view of a radiography system according to Embodiment 1;

FIG. 2 is a schematic perspective view of a radiographic detector according to Embodiment 1;

FIG. 3 is a block diagram illustrating a circuit configuration of the radiography system according to Embodiment 1;

FIG. 4 shows an example of the first data table according to Embodiment 1;

FIG. 5 is a flowchart illustrating a processing by a radiographic detector according to Embodiment 1;

FIG. 6 is a flowchart illustrating a processing by a console according to Embodiment 1;

FIG. 7 is a block diagram illustrating a circuit configuration of a radiography system according to Embodiment 2;

FIG. 8 shows an example of the second data table according to Embodiment 2;

FIG. 9 is a schematic view of a radiography system according to Embodiment 3;

FIG. 10 is a schematic view of a cassette according to Embodiment 3;

FIG. 11 is a cross-sectional view of a cassette mainly illustrating a panel according to Embodiment 3;

FIG. 12 is a circuit diagram mainly illustrating a light detector according to Embodiment 3;

FIG. 13 is a flowchart illustrating a processing by a console according to Embodiment 3;

FIG. 14 is a flowchart illustrating a processing by a cassette according to Embodiment 3; and

FIG. 15 is a flowchart illustrating a processing by an X-ray source according to Embodiment 3.

### PREFERRED EMBODIMENT OF THE INVENTION

We have found that, when an indirect conversion type radiographic detector is used, the characteristic to radiation is different depending on the type of the scintillator and thus it is effective to subject image information obtained by a radiographing to an image processing depending on the type of the scintillator. On the other hand, the image processing depending on the type of the scintillator can be realized if image processing conditions are prepared so as to correspond to the number of the types of scintillators. However, the method of Patent Publication 2 requires a compensation table to be prepared for each radiographic detector, thus only providing limited compensations.

In view of the above, the best mode for carrying out the present invention will be described with reference to the drawings. However, the description of the embodiments intends to show an embodiment that is recognized as the best by the inventor for carrying out the invention and may seemingly include expressions that determine or define terms used in the scope or claims of the invention. However, they are only expressions for specifying the mode that is recognized as the best by the inventor and do not intend to specify or limit terms used in the scope or claims of the invention. The scope of the invention is also not limited by the illustrated examples.

### EMBODIMENT 1

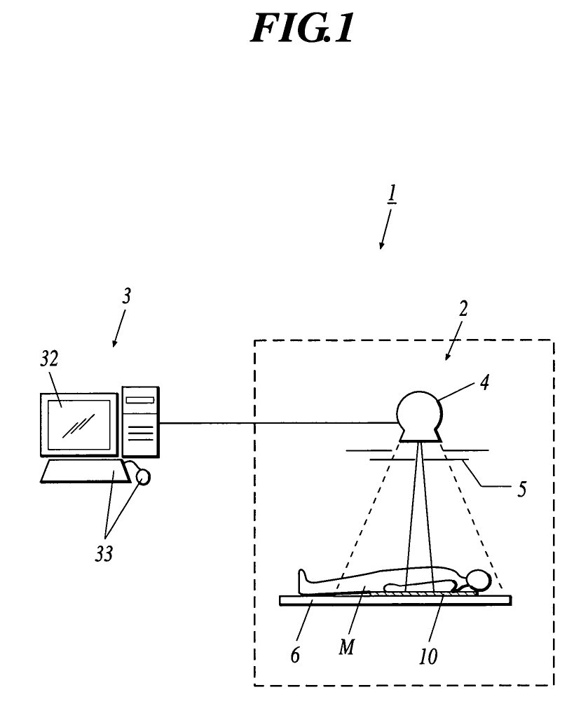

FIG. 1 is a schematic view of a radiography system according to Embodiment 1.

As shown in FIG. 1, the radiography system 1 according to Embodiment 1 is a system particularly effective for a medical diagnosis. The radiography system 1 includes the radiographing apparatus 2 for emitting radiation to the subject (examinee) M to perform the radiographing of the subject M and the console 3 to generate a radiographic image of the subject M.

The radiographing apparatus 2 is provided and used in a medical facility such as a medical clinic or a hospital. The radiographing apparatus 2 includes the radiation source 4 that is provided to emit radiation by being applied with an X-ray tube voltage. At a radiation aperture of the radiation source 4, the aperture apparatus 5 for adjusting a radiation field is provided so that the aperture apparatus 5 can be opened or closed freely. At the lower part of the radiation source 4 within the radiation emission range, the bed 6 is provided on which the subject M is provided. The bed 6 includes the radiographic detector 10 for detecting radiation transmitted through the subject M. The radiographic detector 10 is detachably attached to the bed 6.

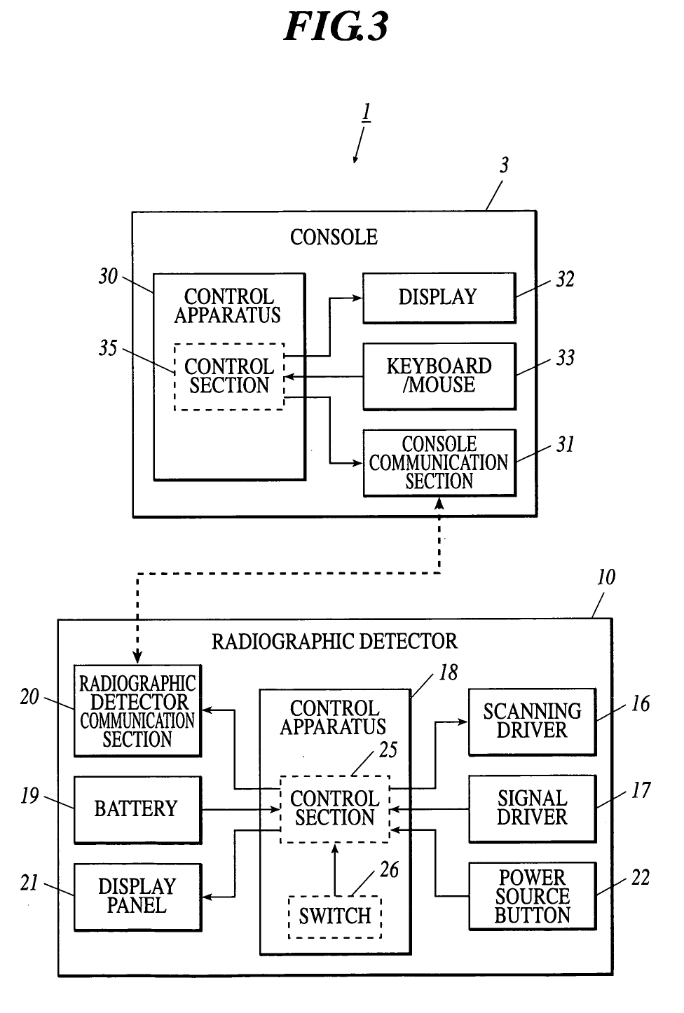

The console 3 is a general-purpose computer that includes the control apparatus 30 (see FIG. 3) to generate, based on the detection result by the radiographic detector 10, the radiographic image of the subject M. The console 3 also includes, for example, the console communication section 31 (including connector, see FIG. 3) for providing communication with the radiographic detector 10, the display 32 for displaying a radiographic image or the like of the subject M; and the keyboard/mouse 33 for inputting various types of information to the control apparatus 30.

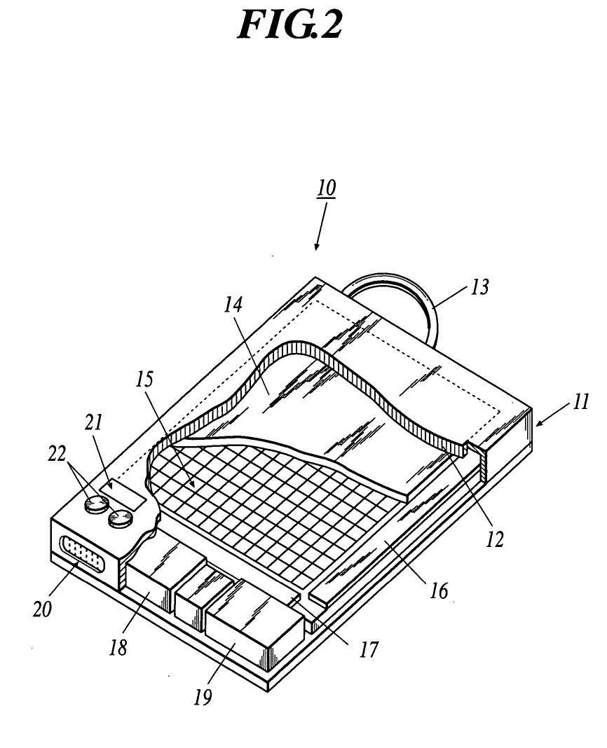

FIG. 2 is a schematic perspective view of the radiographic detector 10.

As shown in FIG. 2, the radiographic detector 10 has the chassis 11 that has the thin shaped and rectangular parallelepiped chassis 11. A part of the top panel of the chassis 11 is the grid 12 that absorbs and removes scatter components of the radiation. A side section of the chassis 11 is provided with the handle 13 for carrying the radiographic detector 10 in an easy manner.

The chassis 11 includes therein the square scintillator 14 to generate fluorescence with strength according to the strength of the radiation. The scintillator 14 is provided by fluorescent material such as CsI:Tl or GOS (Gd₂O₂S:Tb). At the lower part or in the lower direction of the scintillator 14, the flat plate-like fluorescence detection panel 15 is provided for detecting fluorescence. Specifically, at a position opposite to the radiation source 4 of the scintillator 14, the fluorescence detection panel 15 is provided so as to be abutted with the scintillator 14.

In the fluorescence detection panel 15, a great number of photoelectric transducers are arranged in a matrix-like (or grid-like) manner that receives fluorescence to accumulate charge according to the amount of received light. At a side section of the fluorescence detection panel 15, there are provided the scanning driver 16 for sending a pulse to each photoelectric transducer to scan and drive the each photoelectric transducer; and the signal driver 17 for reading the amount of charge accumulated in the each photoelectric transducer.

The chassis 11 includes therein the control apparatus 18 for controlling the operations of the scanning driver 16 and the signal driver 17 and other members; and the battery 19 as a power supply source. The battery 19 is detachably attached to the chassis 11 and can be exchanged with another battery 19 for charging.

The chassis 11 also includes the radiographic detector communication section 20 (including a connector) for performing the communication with the console 3; the display panel 21 for displaying a remaining charge amount or the like of the battery 19; and the power source button 22 for switching ON and OFF of the power source of the radiographic detector 10, for example.

The radiographic detector 10 as described above can be transported and is provided as a cableless transportable cassette in which the battery 19 as an internal power source can supply power to the scanning driver 16, the signal driver 17, the control apparatus 18, the radiographic detector communication section 20, the display panel 21, the power source button 22 or the like. Thereby, it is possible to supply required power from the battery as an internal power source without receiving power supply from an external device. Therefore, it is not necessary that power is supplied from the communication cable connected to a connector of the radiographic detector communication section 20. Further, a communication cable connected to a connector of the radiographic detector communication section 20 may be thin, thus allowing the radiographic detector 10 to be attached in an easier manner.

FIG. 3 is a block diagram illustrating a configuration of the radiography system 1.

As shown in FIG. 3, the control apparatus 18 of the radiographic detector 10 has the control section 25 composed of, for example, a general-purpose CPU (Central Processing Unit), a ROM (Read Only Memory), and a RAM (Random Access Memory). The control section 25 develops a processing program recorded in the ROM into the RAM so that the processing program is executed by the CPU.

The control section 25 is connected with the respective members such as the scanning driver 16, the signal driver 17, the battery 19, the radiographic detector communication section 20, the display panel 21, and the power source button 22. The control section 25 is provided to control each component based on the operation status of the respective members such as the scanning driver 16, the signal driver 17, the battery 19, the radiographic detector communication section 20, the display panel 21, and the power source button 22.

The control apparatus 18 includes, in addition to the above control section 25, the multiple-step-type switch 26 that can be switched. The switch 26 is set depending on the type of the scintillator 14 when the radiographic detector 10 is manufactured. In this embodiment, the type of the scintillator 14 is specified by factors such as the composition, form, or thickness of the scintillator 14.

When the radiographic detector 10 is manufactured with the scintillator 14 having “composition: CsI:Tl, form: columnar crystal, thickness: 300 μm” for example, the switch 26 may be set with “1”. When the scintillator 14 has “composition:CsI:Tl, form: columnar crystal, thickness: 600 μm”, the switch 26 may be set with “2”. When the scintillator 14 has “composition: GOS, form: coating layer, thickness: 600 μm”, the switch 26 may be set with “3”. When the scintillator 14 has “composition: GOS, form: coating layer, thickness: 2 mm”, the switch 26 may be set with “4”.

By reading the status of the switch 26, the control section 25 of the control apparatus 18 recognizes the type of the scintillator 14 and generates “scintillator ID (IDentification)” as scintillator information showing the type of the scintillator 14. The scintillator ID is different for the combination of factors such as the composition, form, or thickness of the scintillator 14 ((i.e., for each type of the scintillator 14).

On the other hand, the control apparatus 30 of the console 3 has the control section 35 composed of a general-purpose CPU (Central Processing Unit), a ROM (Read Only Memory), a RAM (Random Access Memory) or the like. The control section 35 develops a processing program recorded in the ROM into the RAM so that the processing program is executed by the CPU.

The control section 35 is connected with the respective members such as the console communication section 31, the display 32, and the keyboard/mouse 33. The control section 25 controls each component based on the operation status of the respective members such as the console communication section 31, the display 32, and the keyboard/mouse 33.

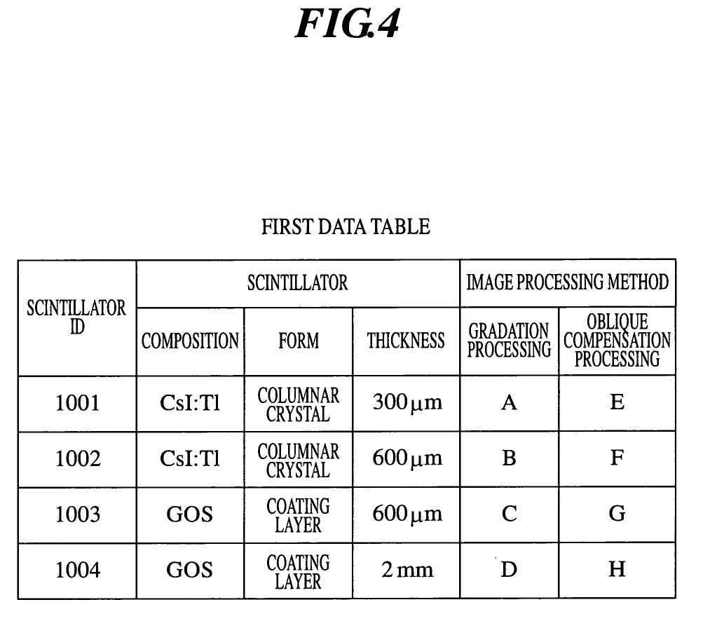

Specifically, the ROM of the control section 35 is recorded with the first data table as shown in FIG. 4 as a part of the processing program. In the first data table, “scintillator ID”, “type of the scintillator 14”, and “image processing method” as the image processing conditions of the respective image processing methods are associated to one another so that the type of the scintillator 14 and the image processing method as the image processing conditions of the respective image processing methods can be specified based on the scintillator ID. Each image processing method is different for each scintillator ID (each type of scintillator 14) and has the image processing contents that are optimal to the type of the scintillator 14 (image processing conditions of each image processing method).

For example, in the respective image processing methods, the contents of “gradation processing” and “frequency processing” are different depending on the type of the scintillator 14 as shown in FIG. 4. The respective marks (alphabets) in FIG. 4 have the following meanings. The term “oblique compensation processing” means a processing for the deblurring of a blurred radiographic image that is caused when the radiation from the radiation source 4 incidents into the scintillator 14 in an oblique direction to generate fluorescence not only at a point at which the radiation incidents into the scintillator 14 but also at a point ahead of the impinged point in a direction along which the radiation progresses (i.e., a point dislocated from the impinged point). The oblique compensation processing as described above is effective to an image at a periphery part far from a point at which radiation incidents into the scintillator 14 in a vertical manner when a radiographing is performed in an oblique direction or when a radiographing is performed while the radiation source 4 being close to the radiographic detector 10.

“A” represents a processing in which an offset default value is large to a predetermined radiation irradiation amount;

“B” represents a processing in which an offset default value is small to a predetermined radiation irradiation amount;

“C” represents a processing in which an offset default value is large to a predetermined radiation irradiation amount; and

“D” represents a processing in which an offset default value is small to a predetermined radiation irradiation amount.

“E” represents a processing in which the oblique compensation processing is not performed;

“F” represents a processing in which the oblique compensation processing is performed to two pixels at the maximum;

“G” represents a processing in which the oblique compensation processing is performed to two pixels at the maximum; and

“H” represents a processing in which the oblique compensation processing is performed to eight pixels at the maximum.

Upon recognizing the scintillator ID, the CPU of the control section 35 specifies, based on the scintillator ID recognized by the above first data table, an image processing method corresponding to the type of the scintillator 14. Then, the CPU of the control section 35 executes the processing program of the specified image processing method. Specifically, the console 3 also works as the image processing apparatus of the present invention. The control section 35 has a function as an image processing section.

In the radiography system 1 as described above, a connector of the radiographic detector communication section 20 of the radiographic detector 10 and a connector of the console communication section 31 are connected by a member such as a communication cable so that the radiographic detector 10 can communicate with the console 3 via the radiographic detector communication section 20 and the console communication section 31.

Although the communication between the radiographic detector 10 and the console 3 was provided in a wired manner as described above, this communication also may be provided by a well-known wireless manner or by a well-known wired or wireless way via a network. This communication is preferably realized, when being realized by a network in particular, by the connection from the console 3 and the radiographic detector 10 to the network that is realized by a wireless LAN (Local Area Network) for example.

Alternatively, another communication configuration also may be used in which the radiographic detector 10 and the console 3 have there between a repeater and the radiographic detector 10 includes an antenna as a communication section of the radiographic detector so that the antenna of the radiographic detector 10 can have communication with the repeater in a wireless manner and the console communication section 31 of the console 3 has communication with the repeater via a communication cable.

Alternatively, another communication configuration also may be used in which the radiographic detector 10 and the console 3 have there between a repeater and the radiographic detector 10 and the console 3 respectively include antennas as a communication section of the radiographic detector and as a console communication section so that the respective antennas of the radiographic detector 10 and the console 3 can have communication with the repeater in a wireless manner. In this case, the console 3 also may be a mobile terminal.

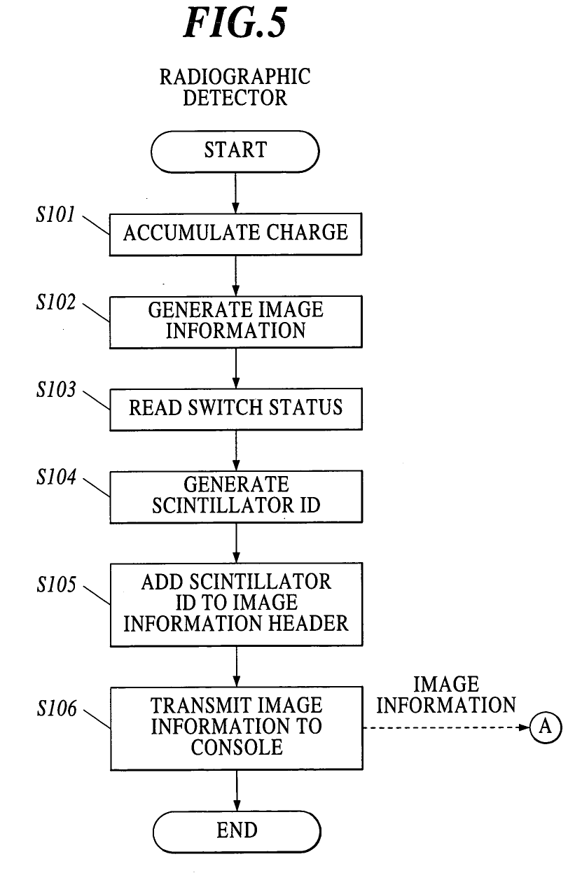

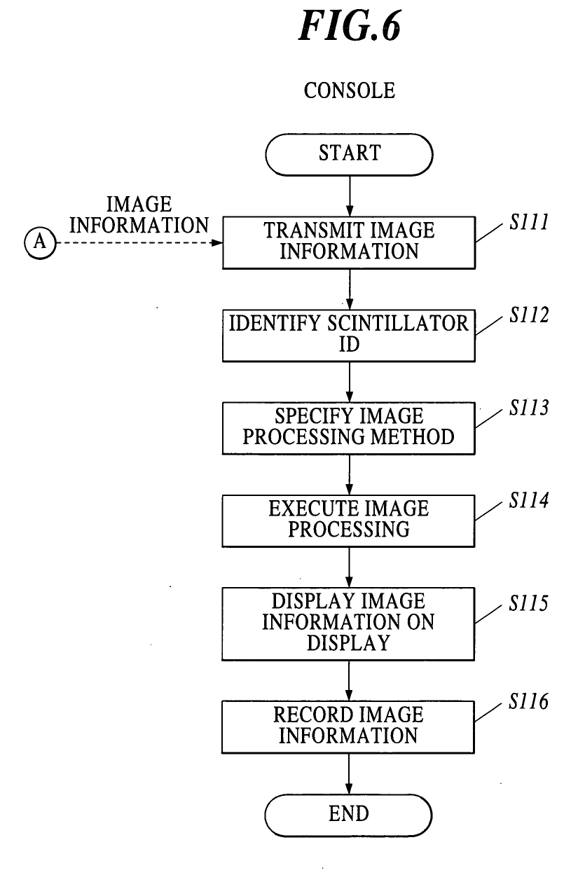

Next, the radiography system 1 will be described with regards to the operation and effect with reference to the flowcharts of FIG. 5 and FIG. 6. In the flowcharts of FIG. 5 and FIG. 6, the processing of Step S101 to Step S106 show the processing in the radiographic detector 10 (see FIG. 5) and the processing of Step S111 to Step S116 show the processing in the console 3 (see FIG. 6).

When the radio graphing of the subject M is started while the radiographic detector 10 and the console 3 can have communication to each other, the radio graphing apparatus 2 emits radiation from the radiation source 4 via the aperture apparatus 5 to the subject M lying on the bed 6. The radiation transmitted through the subject M incidents into the radiographic detector 10. When the radiation incidents into the radiographic detector 10, scatter components in the radiation are absorbed and removed by the grid 12 of the radiographic detector 10 and the radiation incidents into the scintillator 14. Then, the scintillator 14 generates fluorescence with strength according to the strength of the radiation. When the scintillator 14 generates fluorescence, each photoelectric transducer of the fluorescence detection panel 15 receives the fluorescence generated by the scintillator 14 to accumulate the charge according to the amount of the received fluorescence (Step S101).

When each photoelectric transducer accumulates the charge, the control section 25 of the control apparatus 18 controls the scanning driver 16 and the signal driver 17 so that the scanning driver 16 sends a pulse to each photoelectric transducer and the signal driver 17 reads the charge amount accumulated in each photoelectric transducer.

When the signal driver 17 reads the charge amount, the signal driver 17 converts the read charge amount into an electronic signal to output the electronic signal to the control section 25 of the control apparatus 18. Based on the inputted electronic signal, the control section 25 of the control apparatus 18 generates “image information” of the subject M to temporarily store the image information in the RAM as a memory (Step S102) and to read the status of the switch 26 (Step S103), thereby generating “scintillator ID” as scintillator information showing the type of the scintillator 14 (Step S104).

Upon generating the image information and the scintillator ID, the control section 25 of the control apparatus 18 then functions as a scintillator information adding-section to add the scintillator ID as header information to the image information (Step S105) to transmit the image information (including the scintillator ID) from the radiographic detector communication section 20 to the console 3 (Step S106).

The image information is received by the console communication section 31 of the console 3 (Step S111) and the scintillator ID is identified by the control section 35 of the control apparatus 30 based on the received image information (Step S112). Based on the identified scintillator ID, the control section 35 of the control apparatus 30 uses the above first data table (see FIG. 4) to specify an image processing method suitable to the type of the scintillator 14 (Step S113). Then, the control section 35 of the control apparatus 30 subjects the received image information to an image processing according to the specified image processing method (Step S114)

The processing of Step S112 and Step S113 will be described with reference to FIG. 4 for example. When the control section 35 of the control apparatus 30 recognizes that the identified scintillator ID is “1002”, the control section 35 of the control apparatus 30 specifies an image processing method that is unique to the scintillator ID for which the gradation processing is “B” and the oblique compensation processing is “F”, thereby subjecting the image information to an image processing in accordance with the contents of “B” and “F”.

In this gradation processing, an offset value is determined based on a signal statistics value within a radiation field. However, when the offset value is not obtained, the gradation processing is performed based on a default offset value of the gradation processing method corresponding to the scintillator ID. On the other hand, in the oblique compensation processing, a pixel matrix for the oblique compensation is prepared within a range of the maximum number of pixels corresponding to the scintillator ID to perform the oblique compensation.

Alternatively, in addition to or instead of the above gradation processing or oblique compensation processing, “frequency processing” in which a to-be-enhanced frequency is limited depending on the type of the scintillator 14 so that a frequency useful for the diagnosis is enhanced may be performed. In this case, the noise of the image information can be suppressed from being conspicuous.

Returning to FIG. 6, the control section 35 controls the display 32 so that the image information subjected to the image processing in Step S114 is displayed by the display 32 as a radiographic image of the subject M (Step S115). After the image displayed on the display 32 is confirmed by the operator, the image information is stored in an image storage apparatus (not shown).

In the radiography system 1 as described above, the radiographic detector 10 adds the scintillator ID to the image information. The console 3 subjects the image information to an image processing according to the image processing method based on the added scintillator ID. Thus, the image information is subjected to an image processing with the optimal processing contents depending on the type of the scintillator. Therefore, the image information can be subjected to an appropriate image processing depending on the type of the scintillator 14.

### EMBODIMENT 2

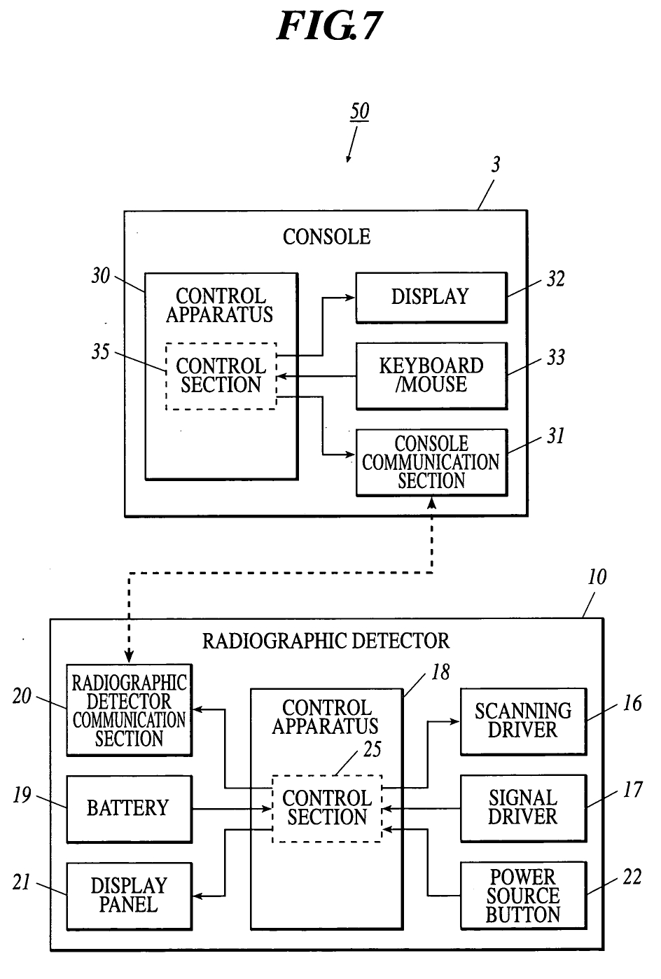

FIG. 7 is a block diagram illustrating a configuration of the radiography system 50 according to Embodiment 2. The structure, operation, and effect of the radiography system 50 according to Embodiment 2 are the same as those of the radiography system 1 except for the following points.

Specifically, as shown in FIG. 7, the control apparatus 18 in the radiographic detector 10 does not include the switch 26 (see FIG. 3). Instead of this, “model ID (Identification)” unique to the model of the radiographic detector 10 is previously stored in (the ROM of) the control section 25 of the control apparatus 18 as detector model information depending on the model of the radiographic detector 10. The model ID is different for each model of the radiographic detector 10. When two or more types of radiographic detectors 10 are compared, the model IDs are the same when these radiographic detectors 10 have the same model and the model ID are different when these radiographic detectors 10 have different models.

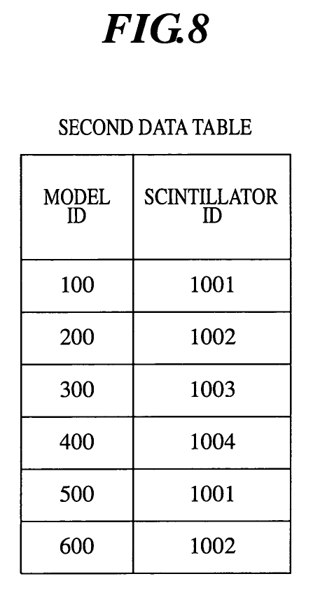

In the console 3, the second data table as shown in FIG. 8 is previously stored in (the ROM of) the control section 35 of the control apparatus 30 as a part of the processing program. In the second data table, “model ID” unique to the model of the radiographic detector 10 is associated with “scintillator ID”. Thus, the scintillator ID can be specified based on the model ID. Furthermore, the type of the scintillator 14 and the image processing method can be specified based on the specified scintillator ID by the first data table of FIG. 4 described in Embodiment 1.

How the model ID corresponds to the scintillator ID, the type of the scintillator 14, and the image processing method will be described with reference to FIG. 4 and FIG. 8. In the case of the models different to each other, the model IDs are different to each other. As shown in the second data table, each model ID corresponds to a scintillator ID. Furthermore, as shown in the first data table, each scintillator ID corresponds to the type of the scintillator 14 and an image processing method. On the other hand, in the case of models of the same type, they have the same model ID, have the same corresponding scintillator ID, and have the same type of the scintillator 14 and the same image processing method.

When recognizing a model ID, the CPU of the control section 35 can use the above second data table to recognize a scintillator ID based on the recognized model ID to subsequently specify, based on the recognized scintillator ID and using the above first data table, an image processing method depending on the type of the scintillator 14 to execute a processing program according to the specified image processing method.

In the radiography system 50 having the structure as described above, the radiographing of the subject M is started and the signal driver 17 converts the amount of the charge accumulated in each photoelectric transducer to an electronic signal to output the electronic signal to the control section 25 of the control apparatus 18. Then, the control section 25 of the control apparatus 18 generates, based on the inputted electronic signal, “image information” of the subject M and functions as a scintillator information adding-section to add the previously stored model ID as header information to the above image information, thereby transmitting the image information (including the model ID) from the radiographic detector communication section 20 to the console 3.

The image information is received by the console communication section 31 of the console 3 and the model ID is identified based on the received image information by the control section 35 of the control apparatus 30. Based on the model ID, the control section 35 of the control apparatus 30 uses the above second data table (see FIG. 8) to recognize the scintillator ID to specify, based on the scintillator ID and using the first data table (see FIG. 4), an image processing method depending on the type of the scintillator 14. Then, the control section 35 of the control apparatus 30 carries out image processing of the received image information in accordance with the specified image processing method.

The above processing will be described with reference to FIG. 8 for example. When the control section 35 of the control apparatus 30 recognizes that the identified model ID is “200”, the control section 35 of the control apparatus 30 recognizes that the scintillator ID is “1002” based on the model ID to specify a corresponding image processing method for which the gradation processing is “B” and the oblique compensation processing is “F” to subject the image information to an image processing according to the respective processing contents of “B” and “F”.

In the above-described radiography system 50, the radiographic detector 10 adds the model ID to the image information and the console 3 specifies the scintillator ID based on the model ID added to the image information to subject the image information to an image processing according to the corresponding image processing method. Thus, the image information is subjected to the image processing with optimal processing contents suitable to the type of the scintillator 14. Thus, the image information can be subjected to an appropriate image processing depending on the type of the scintillator 14. The image processing depending on the type of the scintillator 14 can be performed if image processing conditions are prepared so as to correspond to the number of the types of the scintillators 14, thus eliminating the need for preparing image processing conditions for each radiographic detector 10.

### EMBODIMENT 3

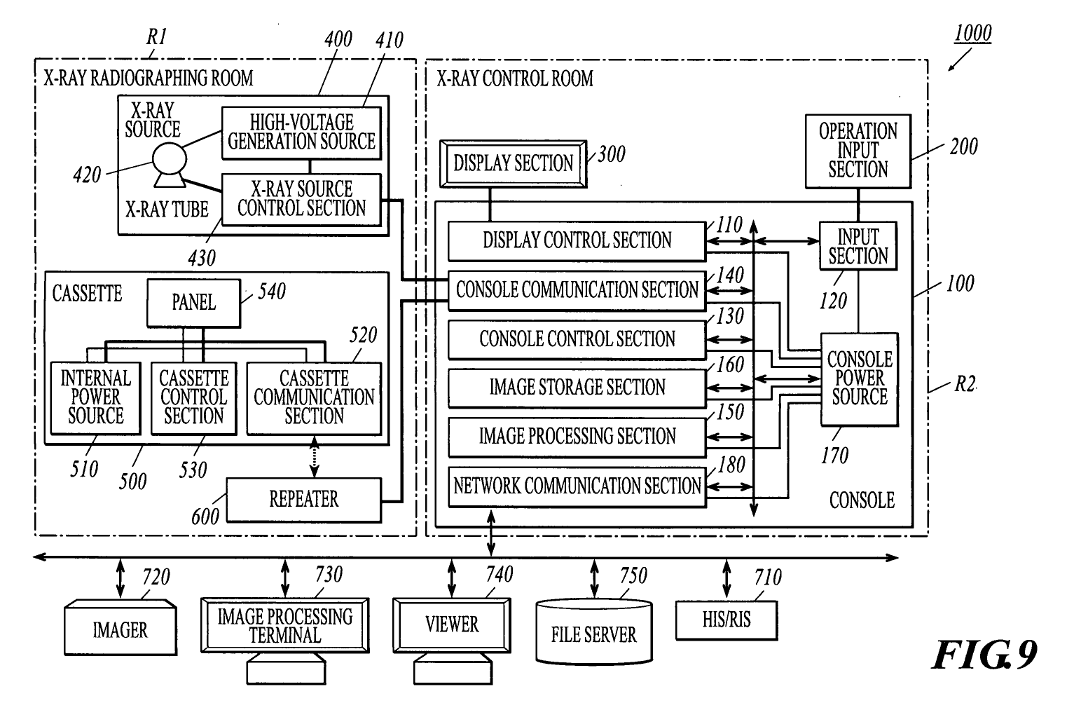

With reference to FIG. 9 to FIG. 15, Embodiment 3 of the radiography system according to the present invention will be described. X-ray is one type of radiation.

As shown in FIG. 9, the radiography system 1000 according to Embodiment 3 is a system particularly useful for a medical diagnosis application. The radiography system 1000 is a system assuming an image radiographing performed in a hospital and is provided, for example, in the radiographing room R1 for emitting X-ray to a subject and the X-ray control room R2 in which an X-ray engineer controls the X-ray emitted to the subject or subjects the X-ray image obtained by the X-ray emission to an image processing.

The X-ray control room R2 includes the console 100. This console 100 is used to control the entirety of the radiography system 1000 to control the radiographing of an X-ray image or to subject the obtained X-ray image to an image processing. The console 100 is an apparatus through which an operator communicates with the cassette 500 and may be connectable with a separately-provided display apparatus or operation apparatus or may be integrated with a display apparatus or an operation apparatus.

The console 100 is connected with the operation input section 200 through which an operator inputs a radiographing preparation instruction, a radiographing instruction, or instruction contents. The operation input section 200 may include, for example, an X-ray irradiation request switch, a touch panel, a mouse, a keyboard, or a joy stick. Through the operation input section 200, instruction contents are inputted such as radiographing conditions (e.g., X-ray tube voltage, X-ray tube current, X-ray irradiation time), conditions for controlling a radiographing (e.g., radiographing timing, portion subjected to radiographing, radiographing method), image processing conditions, image output conditions, cassette selection information, order selection information, or a subject ID.

Furthermore, the console 100 is connected with the display section 300 for displaying an X-ray image or the like and the display is controlled by the display control section 110 constituting the console 100. The display section 300 may be, for example, a monitor (e.g., liquid crystal monitor, CRT (Cathode Ray Tube)), an electronic paper, or an electronic film. The display section 300 displays characters of radiographing conditions or image processing conditions for example and an X-ray image.

The console 100 also includes: the display control section 110; the input section 120; the console control section 130; the console communication section 140; the image processing section 150; the image storage section 160; the console power source section 170; and the network communication section 180 for example. The display control section 110, the input section 120, the console control section 130, the console communication section 140, the image processing section 150, the image storage section 160, the console power source section 170, and the network communication section 180 are respectively connected with buses to provide data exchange.

The input section 120 receives instruction contents from the operation input section 200.

The console control section 130 determines, based on the instruction contents received by the input section 120 and/or the order information of HIS/RIS710, radiographing conditions to send the information regarding the radiographing conditions via the console communication section 140 to the X-ray source 400 and the cassette 500 to control the X-ray source 400 and the cassette 500, thereby providing an Image radiographing. The console control section 130 also causes the X-ray image data received by the console communication section 140 from the cassette 500 to be temporarily stored in the image storage section 160. The console control section 130 also causes the image processing section 150 to prepare thumbnail image data based on the X-ray image data temporarily stored in the image storage section 160. Based on the prepared thumbnail image data, the display control section 110 controls the display section 300 so that the display section 300 displays the thumbnail image. Then, the console control section 130 provides a control so that the X-ray image data is subjected by the image processing section 150 to such an image processing that is based on the instruction contents received by the input section 120 and/or the order information of HIS/RIS710 and then this image-processed X-ray image data is stored by the image storage section 160. Then, the console control section 130 controls the display control section 110 so that, the display section 300 displays, based on the X-ray image data obtained by the image processing by the image processing section 150, the thumbnail image obtained by the processing. Furthermore, the console control section 130 performs, based on the instruction contents subsequently received by the input section 120 from the operation input section 200, the second image processing of the X-ray image data, the display of the result of the second image processing, or the transfer, storage, or display of the X-ray image data on an external apparatus on the network.

The console control section 130 may use a mother board including a CPU (Central Processing Unit) and a memory (e.g., RAM (Random Access Memory) or a ROM (Read Only Memory)).

The CPU reads the program stored in the ROM or the hard disk to develop the program on the RAM, thereby controlling, based on the developed program, the respective parts of the console 100, the X-ray source 400, the cassette 500, and an external apparatus. The CPU also reads various processing programs stored in the ROM or the hard disk (e.g., system program) to develop the program on the RAM, thereby executing various processing (which will be described later).

The RAM is a volatile memory that forms a work area to store temporarily various programs that are read, in various processing executed and controlled by the CPU, by the ROM and can be executed by the CPU, an input, or output data for example.

The ROM is a non-volatile memory for example that stores a system program executed by the CPU or various programs corresponding to the system program for example. These programs are stored in the form of readable program codes and the CPU sequentially executes operations in accordance with the program codes.

Instead of the ROM, a hard disk also may be used. In this case, the hard disk stores a system program executed by the CPU and various application programs. The hard disk also may be configured so that a part or the entirety thereof receives and stores, from the console communication section 140, various application programs such as a program of the present invention from another machine (e.g., server) via a transmission medium of a network line. The CPU also may be configured to receive, from a storage apparatus such as a hard disk of a server provided on a network, various application programs such as the program of the present invention to develop the program on the RAM, thereby providing various processing such as the processing of the present invention.

Specifically, in the console control section 130, the first data table (see FIG. 4) described in Embodiment 1 is previously stored in the ROM. Thus, when the CPU recognizes a scintillator ID showing the type of the scintillator 541 (which will be described later), an image processing method depending on the type of the scintillator 541 can be specified based on the scintillator ID recognized using the first data table. Specifically, the console control section 130 in this embodiment has a function as an image processing method storage section.

The display control section 110 controls the display section 300 so that the display section 300 displays an image or characters based on the control by the console control section 130 and based on the X-ray image data and the character data. The display control section 110 may use a graphic board for example.

The console communication section 140 is connected with the X-ray source 400 and the repeater 600 via a communication cable, respectively so that the console communication section 140 can have communication with the cassette 500 via the repeater 600. The console communication section 140 can send a control signal based on the instruction contents by analog communication or digital communication to the X-ray source 400 and the cassette 500 and can receive X-ray image data from the cassette 500.

The console communication section 140 is connected with the X-ray source 400 and the repeater 600 via a communication cable that is detachable. When the communication cable is connected, image transfer can be performed with a high speed and thus it is possible to perform the acquisition of an X-ray image by a radiographing, an X-ray image processing, or the check of an X-ray image within a shorter period of time.

The image processing section 150 subjects the X-ray image data received by the console communication section 140 from the cassette 500 to an image processing. The image processing section 150 subjects the X-ray image data to a compensation processing, expansion/compression processing, a space filtering processing, a recursive processing, a gradation processing, a scattering radiation compensation processing, a grid compensation processing, a frequency enhancement processing, or a dynamic range (DR) compression processing for example.

The image storage section 160 temporarily stores the X-ray image data received by the console communication section 140 from the cassette 500 or stores the processed X-ray image data. The image storage section 160 may be a hard disk as a storage apparatus having a large capacity and a high speed, a hard disk array (e.g., RAID (Redundant Array of Independent Disks)), or a silicon disk for example.

The console power source section 170 is supplied with power from an external power source (not shown) (e.g., AC power source) or an internal power source (not shown) (e.g., battery, electric cell) to supply power to the respective components constituting the console 100.

The external power source of the console power source section 170 is detachable. When the console power source section 170 is supplied with power from an external power source, radiographing can be performed for a long time because the need for charging is eliminated.

The network communication section 180 uses a LAN (Local Area Network) to provide the communication between the console 100 and the external apparatus. The network communication section 180 can provide communication to external apparatuses, including, for example, the HIS/RIS (Hospital Information System/Radiology Information System) terminal 710, the imager 720, the image processing terminal 730, the viewer 740, and the file server 750. The network communication section 180 outputs X-ray image data to an external apparatus according to a predetermined protocol such as DICOM (Digital Imaging and Communications in Medicine).

The HIS/RIS terminal 710 obtains, from the HIS/RIS, the information regarding the subject or the portion to be subjected to radiographing and/or the radiographing method for example to provide the data to the console 100. The imager 720 records, based on the X-ray image data outputted from the console 100, the X-ray image on an image recording medium (e.g., film). The image processing terminal 730 performs an image processing of the X-ray image data outputted from the console 100 or a processing for CAD (Computer Aided Diagnosis) to store the result in the file server 750. The viewer 740 displays, based on the X-ray image data outputted from the console 100, the X-ray image. The file server 750 is a file server that stores the X-ray image data having been subjected to the image processing. The network communication section 180 outputs the X-ray image data to an external apparatus in accordance with a predetermined protocol such as DICOM (Digital Imaging and Communications in Medicine).

Although this embodiment described a case in which the display control section 110 and the console control section 130 are provided separately, the display control section 110 also may be integrated with the console control section 130. For example, the console control section 130 also may be a mother board including a CPU and a memory and the display control section 110 also may be a graphic subsystem included in this mother board. Alternatively, the console control section 130 also may function as a display control section. Although this embodiment provided the image processing section 150 and the console control section 130 separately, the console control section 130 also may function as an image processing section.

The radiographing room R1 includes the X-ray source 400 and the cassette 500. The X-ray source 400 irradiates X-ray to the subject. The cassette 500 is a mobile radiographic detector that detects the X-ray transmitted through the subject to generate X-ray image data as image information.

Furthermore, the radiographing room R1 includes the repeater 600. The repeater 600 has wireless communication with the cassette 500. The repeater 600 has communication with the console 100 via a communication cable. Then, X-ray image data obtained by the cassette 500 is sent via the repeater 600 to the console 100 and the console 100 and the cassette 500 have there between the communication of a control signal or various information. In this manner, the console 100 is connected to the repeater 600 via a cable and the radiographing room R1 includes the repeater 600, thus providing favorable wireless communication between the repeater 600 and the console 100 even when the cassette 500 is used in the radiographing room R1 blocked by a radiation block member.

Alternatively, the repeater 600 also may have a function as a charger of the cassette 500 and a function as a holder when the cassette 500 is not used. The repeater 600 includes a connector. When this connector is connected to the cassette 500, the internal power source 510 of the cassette 500 is charged. Then, the repeater 600 is preferably formed so that the cassette 500 can be attached thereto or detached there from easily. In the present invention, the repeater 600 has, in addition to the function as a charger of the cassette 500, a function as a holder when the cassette 500 is not used.

The X-ray source 400 includes the high voltage generation source 410 to generate a high voltage and the X-ray tube 420 to generate X-ray when being applied with a high voltage from the high voltage generation source 410. The X-ray irradiation opening of the X-ray tube 420 includes an X-ray aperture apparatus (not shown) for adjusting an X-ray emission range. The X-ray aperture apparatus controls the direction along which the X-ray is irradiated according to a control signal from the console 100, thus adjusting the X-ray emission range depending on the radiographing region. Furthermore, the X-ray source 400 includes the X-ray source control section 430. The high voltage generation source 410 and the X-ray tube 420 are connected with the X-ray source control section 430, respectively. The X-ray source control section 430 controls, based on a control signal sent from the console communication section 140, the respective components of the X-ray source 400. Specifically, the X-ray source control section 430 controls the high voltage generation source 410 and the X-ray tube 420.

The cassette 500 is impinged with the X-ray transmitted through the X-ray source 400. The position of the cassette 500 is adjusted by X-ray prior to a radiographing operation so that X-ray is transmitted through a desired position of the subject. The cassette 500 includes the internal power source 510, the cassette communication section 520, the cassette control section 530, and the panel 540. The internal power source 510, the cassette communication section 520, the cassette control section 530, and the panel 540 are connected to buses in the cassette 500, respectively.

The internal power source 510 supplies power to the respective components included in the cassette 500. The internal power source 510 includes a capacitor that can be charged and that can store power consumed by a radiographing. The capacitor may be an electrolysis double layer capacitor. The internal power source 510 may be a primary cell that must be exchanged with a new one (e.g., manganese electric cell, nickel/cadmium electric cell, mercury cell, lead cell) or a secondary cell that can be charged.

The internal power source 510 preferably has a capacity that is determined, from the viewpoint of the radiographing efficiency, to provide continuous radiographing of the maximum-sized X-ray images in an amount of 4 or more (7 or more preferably). At the same time, the internal power source 510 preferably has a capacity that is determined, from the viewpoint of smaller size, lighter weight, and lower cost, to provide continuous radiographing of the maximum-sized X-ray images in an amount of 100 or less (50 or less more preferably).

The cassette communication section 520 as a communication section of the radiographic detector is provided so as to have wireless communication with the console communication section 140 via the repeater 600. Thus, the cassette communication section 520 can send or receive a signal to or from the console communication section 140 and can send X-ray image data to the console communication section 140.

The cassette control section 530 is composed of a CPU (Central Processing Unit), a ROM (Read Only Memory), a RAM (Random Access Memory) or the like in which the CPU develops, based on the control signal received by the cassette communication section 520, a processing program recorded in the ROM into the RAM while executing the program, thereby controlling the respective components of the cassette 500. Specifically, the ROM of the cassette control section 53 stores therein “scintillator ID” as scintillator information showing the type of the scintillator 541 (which will be described later). As in the description regarding Embodiment 1, the type of the scintillator 541 is specified based on factors such as composition, form, or thickness. Thus, the scintillator ID is different for the combination of factors such as the composition, form, or thickness of the scintillator 541 ((i.e., for each type of the scintillator 541).

The panel 540 outputs the X-ray image data based on the X-ray transmitted through the subject. The panel 540 of this embodiment is an indirect type flat panel detector (FPD).

From the viewpoint of the diagnostic ability in the diagnosis using an X-ray image, the panel 540 is preferably composed of 1000×1000 pixels (more preferably, 2000×2000 pixels or more). From the viewpoints of the limit of visual perception of human and the image processing speed of an X-ray image, the panel 540 is preferably composed of 10000×10000 pixels or less (more preferably, 6000×6000 pixels or less). From the viewpoint of the diagnostic ability in the diagnosis using an X-ray image, the size of a radiographing region of the panel 540 is preferably an area of 10 cm×10 cm or more (more preferably, 20 cm×20 cm or more). From the viewpoint of an easy handling of a cassette, the size of a radiographing region of the panel 540 is preferably an area of 70 cm×70 cm or less (more preferably, 50 cm×50 cm or less). From the viewpoint of the reduction of an amount of exposure to X-ray, the size of one pixel in the panel 540 is preferably 40 μm×40 μm or more (more preferably, 70 μm×70 μm or more). From the viewpoint of the diagnostic ability in the diagnosis using an X-ray image, the size of one pixel in the panel 540 panel is preferably 200 μm×200 μm or less (more preferably, 160 μm×160 μm or less). In this embodiment, the panel 540 is composed of 4096×3072 pixels, the radiographing region has an area of 430 mm×320 mm, and the size of one pixel is 105 μm×105 μm.

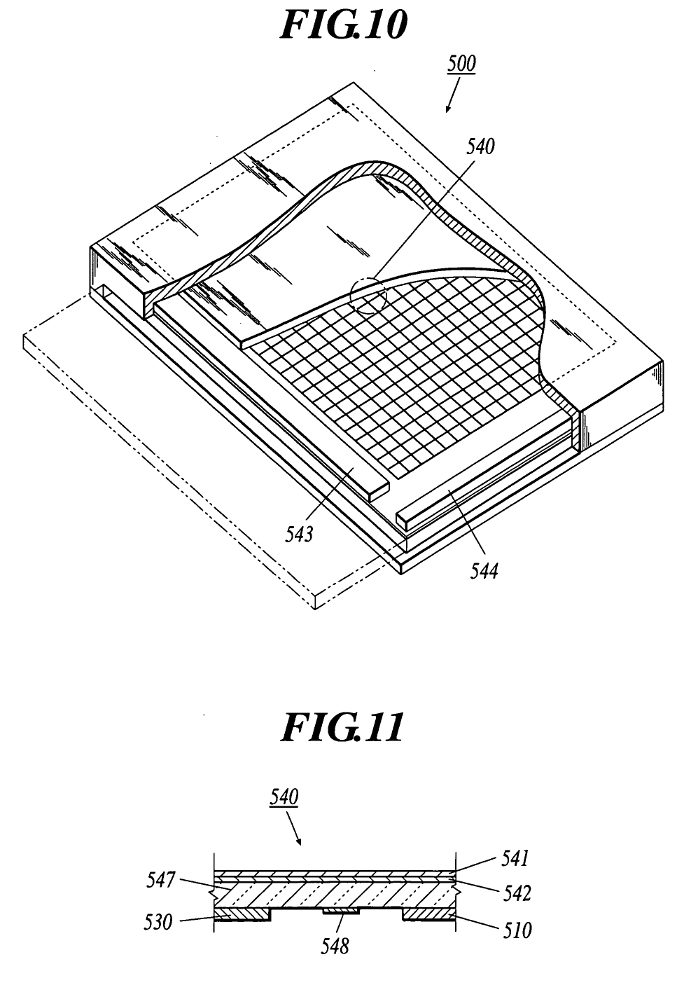

FIG. 10 is a schematic perspective view of the cassette 500. FIG. 11 is a cross-sectional view mainly illustrating the panel 540 in the cassette 500.

Although this embodiment describes the examples shown in FIG. 10 and FIG. 11, the present invention is not limited to them. The present invention also can be applied to examples in which the scintillator has a different thickness or type or the panel has a different area as an imaging region. The higher thickness the scintillator has, the higher the sensitivity is. The lower thickness the scintillator has, the higher the space resolution is. The spectroscopy sensitivity is also different depending on the type of the scintillator.

At the uppermost layer of the panel 540, the scintillator 541 extends that detects the X-ray transmitted through the subject to convert the detected X-ray to fluorescence in a visible region (hereinafter referred to as “visible light”).

The scintillator 541 includes fluorescence material as a main component. The scintillator 541 is a layer in which the irradiated X-ray causes base substance as fluorescence material to be excited (or to be absorbed) and the recombination energy is used to emit visible light. This fluorescence material includes, for example, the one in which base substance such as GOS, CaWO₄, or CdWO₄ is used to emit fluorescence or the one in which emission center substance added to base substance such as CsI:Tl or ZnS:Ag is used to emit fluorescence.

At the lower side of the scintillator 541, the light detector 542 made of amorphous silicon is layered to extend. This light detector 542 converts visible light emitted from the scintillator 541 to electric energy to output the energy.

Here, the circuit configuration will be described mainly with regards to the light detector 542.

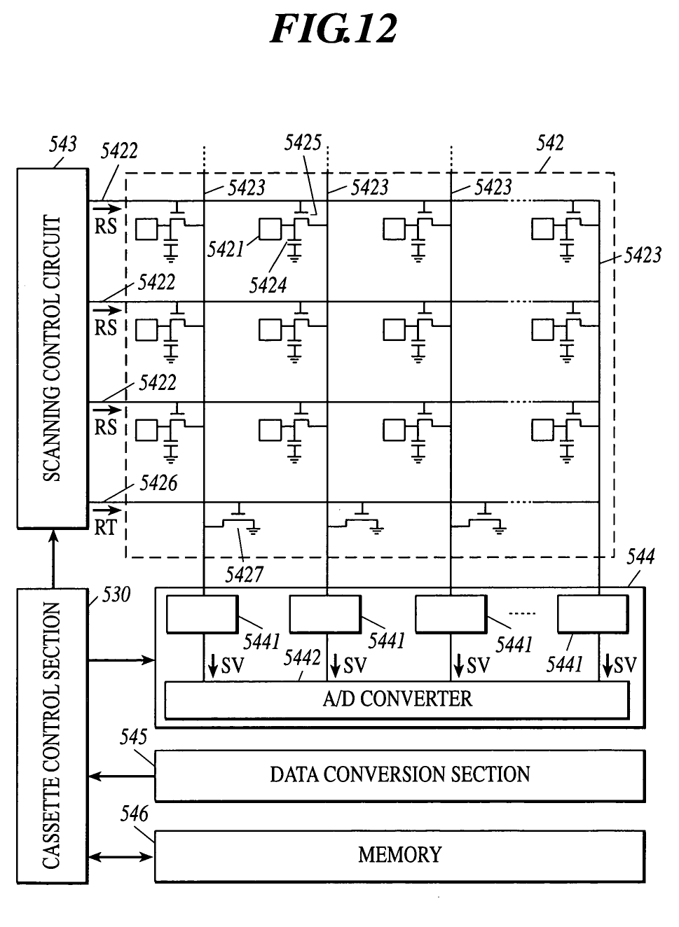

As shown in FIG. 12, in the light detector 542, the collection electrodes 5421 are arranged in a two-dimensional manner for reading the accumulated electric energy depending on the strength of the emitted X-ray. This collection electrode 5421 is used as one electrode of the capacitor 5424 so that electric energy can be accumulated in the capacitor 5424. Here, one collection electrode 5421 corresponds to one pixel of the X-ray image data.

Those collection electrodes 5421 that are adjacent to each other have there between the scanning line 5422 and the signal line 5423. The scanning line 5422 is orthogonal to the signal line 5423.

The capacitor 5424 is connected with the switching thin film transistor 5425 (TFT, hereinafter referred to as “transistor”) for controlling the storage and reading of electric energy. In the transistor 5425, a drain electrode or a source electrode is connected to the collection electrode 5421 and a gate electrode is connected to the scanning line 5422. When the drain electrode is connected to the scanning line 5422, the source electrode is connected to the signal line 5423. When the source electrode is connected to the collection electrode 5421, the drain electrode is connected to the signal line 5423. In the panel 542, the signal line 5423 includes the transistor 5427 for initialization that is connected with a drain electrode for example. The source electrode of this transistor 5427 is grounded. The gate electrode is connected with the reset line 5426.

The transistor 5425 and the transistor 5427 are preferably formed by a silicon layer structure or organic semiconductor.

The scanning drive circuit 543 is connected with the reset line 5426 that receives the reset signal RT from the scanning drive circuit 543 so that the reset line 5426 is orthogonal to the signal line 5423. The reset line 5426 is connected with the gate electrode of the initialization transistor 5427 that is in an ON status by the reset signal RT. In the initialization transistor 5427, the gate electrode is connected with the reset line 5426, the drain electrode is connected with the signal line 5423, and the source electrode is grounded. When the source electrode is connected with the signal line 5423, the drain electrode is grounded.

When the scanning drive circuit 543 supplies the reset signal RT to cause the initialization transistor 5427 to be in an ON status and the scanning drive circuit 543 supplies the read signal RS to cause the transistor 5425 to be in an ON status, electric energy accumulated in the capacitor 5424 is discharged via the transistor 5425 to the outside of the light detector 542. Hereinafter, when the reset signal RT is supplied and electric energy accumulated in the capacitor 5424 is discharged to the outside of the light detector 542, it is called as the reset (initialization) of the light detector 542.

The scanning line 5422 is connected with the scanning drive circuit 543 for supplying the read signal RS to the scanning line 5422. When the transistor 5425 is connected to the scanning line 5422 supplied with the read signal RS, the transistor 5425 is in an ON status to read electric energy accumulated in the capacitor 5424 connected with the transistor 5425 to supply the energy to the signal line 5423. Specifically, by driving the transistor 5425, a signal for each pixel of the X-ray image data can be generated.

The signal line 5423 is connected with the signal reading circuit 544. This signal reading circuit 544 is supplied with electric energy that was accumulated in the capacitor 5424 before being read by the signal line 5423. The signal reading circuit 544 includes: the signal converter 5441 for supplying, to the A/D converter 5442, the voltage signal SV proportional to the amount of the electric energy supplied to the signal reading circuit 544; and the A/D converter 5442 for converting the voltage signal SV from the signal converter 5441 to a digital signal to supply the signal to the data conversion section 545.

The signal reading circuit 544 is connected with the data conversion section 545. This data conversion section 545 generates X-ray image data based on the digital signal supplied from the signal reading circuit 544.

When X-ray image data having a high resolution is not required or when X-ray image data is desired to be obtained quickly, the console control section 130 sends, in accordance with a radiographing method selected by an operator, the received control signal (e.g., thinning-out, pixel average, region extraction) to the cassette control section 530. The cassette control section 530 provides a control so that thinning-out, pixel averaging, and region extraction (which will be described later) are performed in accordance with the received control signal (e.g., thinning-out, pixel average, region extraction).

The thinning-out is performed by reading only an odd number column or an even number column to thin-out the number of pixels to be read to ¼ of the number of all pixels or to 1/9 or 1/16 of the number of all pixels for example. The thinning-out method is not limited to this method.

A pixel average can be calculated by simultaneously driving a plurality of scanning lines 5422 to perform an analog addition of two pixels in the same column direction. The pixel average calculation is not limited to the addition of two pixels and also may be easily performed by performing an analog addition of a plurality of pixels in a column signal wiring direction. Furthermore, with regards to the addition in the row direction, an A/D conversion output can be performed to subsequently subject neighboring pixels to a digital addition with the above-described analog addition, thereby obtaining addition value of a square pixel (e.g., 2×2). By them, data can be read with a high speed without wasting irradiated X-ray.

A region extraction is performed by a means for limiting a region in which X-ray image data is grabbed. This is to specify, based on the instruction contents of the radiographing method for example, a region in which required X-ray image data is obtained so that, based on this specified region in which required X-ray image data is obtained, the cassette control section 530 changes the range within which data is grabbed by the scanning drive circuit 543, thereby allowing this changed grabbing range to be driven by the panel 540.

The data conversion section 545 is connected with the memory 546. This memory 546 stores X-ray image data generated by the data conversion section 545. The memory 546 previously stores data for gain compensation.

The memory 546 is composed of a RAM (Random Access Memory) and a non-volatile memory. This memory 546 can sequentially write the X-ray image data sequentially generated by the data conversion section 545 into the RAM to subsequently collectively write the data into the non-volatile memory. The non-volatile memory is composed of two or more memory components (e.g., EEPROM, flash memory) in which one memory component can be erased while the other can be written with data.

From the viewpoint of the radiographing efficiency, the memory 546 preferably has a capacity corresponding to 4 or more images having the maximum data size (more preferably 10 or more such images). From the viewpoint of a lower cost, the memory 546 preferably has a capacity corresponding to 1000 or less images having the maximum data size (more preferably 100 or less such images).

At the lower layer of the light detector 542, there is provided the support base 547 on a flat plate formed of a grass substrate. The support base 547 supports the layered structure of the scintillator 541 and the light detector 542.

At the lower face of the support base 547, the X-ray amount sensor 548 is provided.. The X-ray amount sensor 548 detects X-ray amount transmitted through the light detector 542 to transmit, when the X-ray amount reaches a predetermined amount, a predetermined X-ray amount signal to the cassette control section 530. In this embodiment, an amorphous silicon light receiving element is used as the X-ray amount sensor 548. The X-ray amount sensor 548 is not limited to this and also may be an X-ray sensor in which a light receiving element by crystalline silicon for example is used to detect direct X-ray or also may be a sensor in which scintillator is used to detect fluorescence.

As described above, the cassette 500 is driven by power from the internal power source 510 and is the transportable and cable less one in which the cassette communication section 520 and the console communication section 140 have communication via a wireless communication. Thus, the cassette 500 can be interlocked with the console 100 while providing good operation to improve the radiographing efficiency.

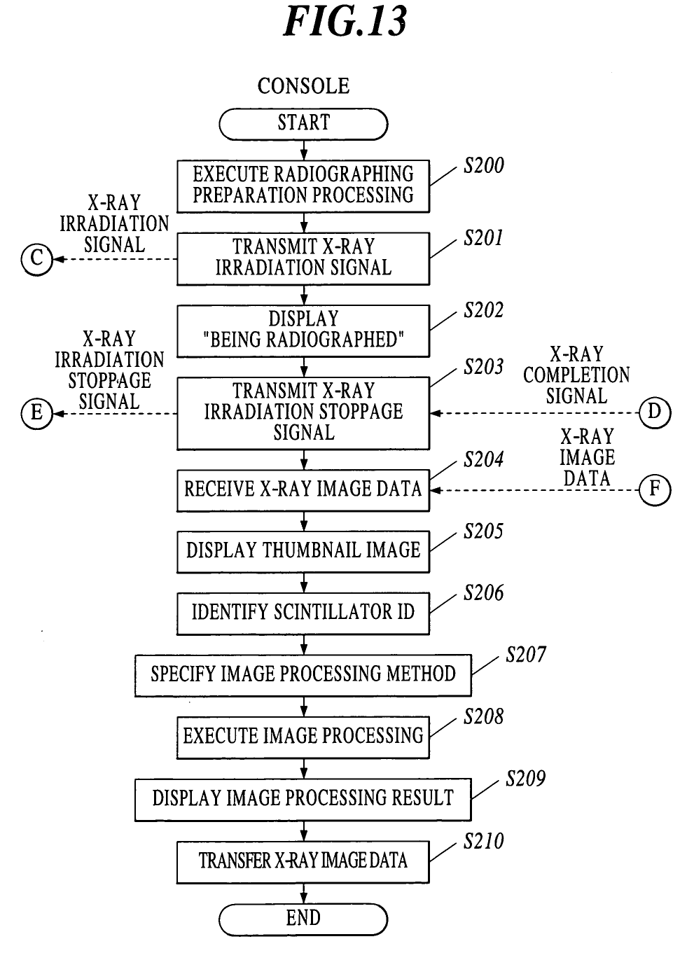

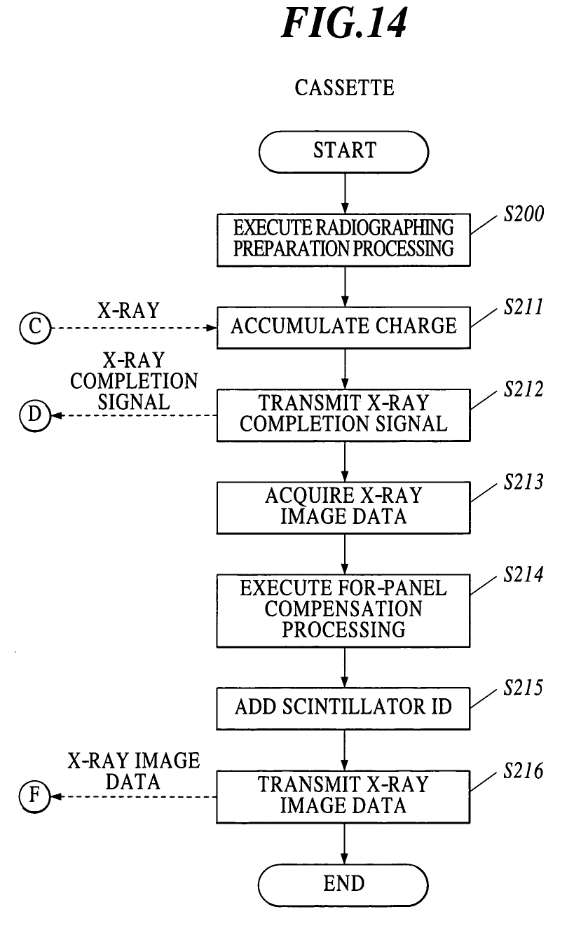

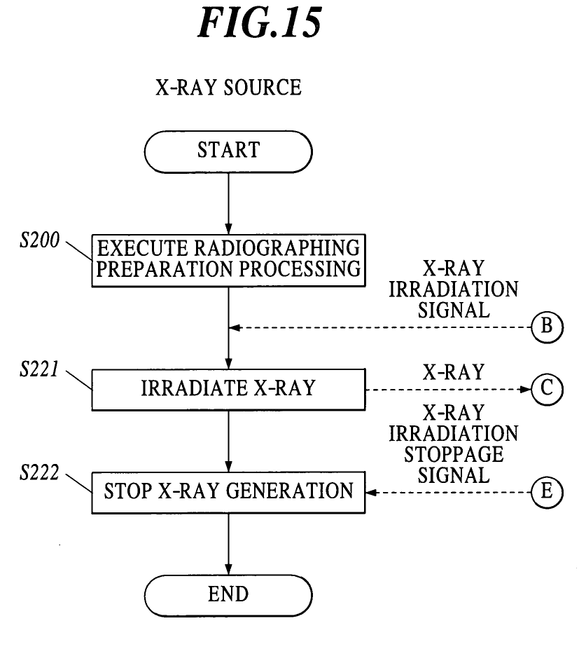

Next, the radiography system 1000 will be described with regards to the operation and effect with reference to FIG. 13 to FIG. 15. In the flowcharts of FIG. 13 to FIG. 15, the processing of Step S201 to Step S210 represent the processing in the console 100 (see FIG. 13), the processing of the Step S211 to Step S216 represent the processing in the cassette 500 (see FIG. 14), and the processing of Step S221 to Step S222 represent the processing in the X-ray source 400 (see FIG. 15).

Step S200 performs radiographing preparation processing in the console 100, the cassette 500, and the X-ray source 400, respectively.

The scanning drive circuit 543 is kept in an OFF status until a radiographing preparation instruction signal from the console control section 130 is received. In order to keep the scanning drive circuit 543 in an OFF status, the scanning line 5422, the signal line 5423, and the reset line 5426 are caused to have the same potential and the collection electrode 5421 is not applied with a bias potential. Alternatively, the power source of the signal reading circuit 544 also may be kept in an OFF status and the scanning line 5422, the signal line 5423, and the reset line 5426 also may be caused to have the GND potential.

The status in which the scanning drive circuit 543 and the signal reading circuit 544 are not applied with a bias potential is classified into a radiographing waiting mode and a sleep mode.

In the radiographing waiting mode, a photo diode is not applied with a bias potential and the scanning drive circuit 543 and the signal reading circuit 544 can be started quickly. Thus, the scanning drive circuit 543 and the signal reading circuit 544 are also preferably not supplied with power because it can further suppress power consumption. In the radiographing waiting mode, no signal is generated and thus the data conversion section 545 is also preferably not supplied with power because it can further suppress power consumption.

Furthermore, the sleep mode is also preferably provided that provides further smaller power consumption than in the case of the radiographing waiting mode. The sleep mode is preferably started after the previous mode after a radiographic image is sent to the console 100 completely.

In the sleep mode, only functions required for the switching, based on an instruction from the console 100, to the radiographing waiting mode are activated and a high-speed transmission function or the entire transmission function of the cassette communication section 520 and/or the power supply to the memory is/are preferably stopped. Specifically, in the sleep mode, a bias potential is not applied to the photo diode and power is not preferably supplied to the scanning drive circuit 543, the signal reading circuit 544, the data conversion section 545, the memory 546, and a high-speed transmission function or the entire transmission function of the cassette communication section 520. This can further reduce wasteful power consumption.

In the radiographing waiting mode and the sleep mode control as described above under which power consumption per a unit time is lower than that in the radiographing-possible status, the scanning line 5422, the signal line 5423, and the reset line 5426 are caused to have the same potential and the collection electrode 5421 is not applied with a bias potential (i.e., a plurality of pixels are substantially not applied with voltage). Thus, PD or TFT can be substantially applied with voltage, thereby suppressing the deterioration (i.e., the deterioration of a plurality of pixels). This also can reduce wasteful power consumption.

The term “radiographing-possible status” means a status in which a radiographing operation can immediately provide X-ray image data. The term “radiographing operation” means an operation required for performing a radiographing to obtain X-ray image data. For example, in the case of the panel shown by the embodiment, the “radiographing operation” applies to the respective operations of a panel initialization, accumulation of electric energy generated by emission of radiation, reading of an electronic signal, and the conversion of X-ray image to data.

Then, when the 1st switch of the X-ray irradiation switch is turned ON, when the input section 120 receives instruction contents for a radiographing operation via the operation input section 200 (e.g., when the input section 120 is inputted with a predetermined item (e.g., subject information, radiographing information), or when the input section 120 receives from the HIS/RIS 710 the order information for example, then the console control section 130 determines radiographing conditions based on the instruction contents by the operator or the order information from the HIS/RIS 710 to send a radiographing preparation instruction signal based on these radiographing conditions to the X-ray source control section 430 and the cassette control section 530 via the console communication section 140, thereby providing the switching to the radiographing-possible status.

When receiving the radiographing preparation instruction signal, the X-ray source control section 430 drives and controls the high voltage generation source 410 so that a high voltage is applied to the X-ray tube 420.

When receiving the radiographing preparation instruction signal, the cassette control section 530 switches to the radiographing-possible status. Specifically, until a radiographing instruction is inputted in the radiographing-possible status, all pixels are reset with a predetermined interval repeatedly, thus preventing the accumulation of electric energy in the capacitor 5424 due to dark current. Since the time during which the radiographing-possible status is continued is unknown, this predetermined interval is set to be longer than that in the radiographing operation and the time during which the transistor 5425 is ON is set to be shorter than that in the radiographing operation. As a result, readout operations that are burdensome to the transistor 5425 are reduced in the radiographing-possible status.

When the switching to the radiographing-possible status is provided, the cassette control section 530 sends to the console 100 a signal representing the switching to the radiographing-possible status. When receiving the signal representing the switching to the radiographing-possible status, the console control section 130 controls the display control section 110 so that the display section 300 displays a cassette radiographing-possible status to show that the cassette 500 is now in the radiographing-possible status.

When the radiographing instruction is inputted to the console control section 130, the console control section 130 determines radiographing conditions based on the instruction contents from the operator or the order information from the HIS/RIS710 or the like to transmit the information regarding the radiographing conditions to the X-ray source control section 430 and the cassette control section 530 via the console communication section 140.

When the console control section 130 receives an X-ray irradiation instruction from an operator for switching ON the X-ray irradiation switch again for example, the console control section 130 sends the radiographing instruction signal to the cassette control section 530 of the cassette 500. After being inputted with the X-ray irradiation instruction, the console control section 130 controls the X-ray source 400 and the cassette 500 in a synchronized manner to provide a radiographing operation.

Upon receiving the radiographing instruction signal, the cassette control section 530 initializes the panel 540 and the panel 540 can now accumulate electric energy.

Specifically, a refresh is performed in which all pixels exclusive for an imaging sequence are reset a predetermined number of times and all pixels exclusive for a status in which electric energy is accumulated are reset, thus providing transition to an electric energy accumulation status. All pixels exclusive for an imaging sequence are reset because a period from an irradiation request to the completion of the radiographing preparation is required to be short for practical reasons. Furthermore, the driving of the imaging sequence is started immediately whenever an irradiation request is caused, whatever the driving status of the radiographing-possible status is. By reducing the period from the irradiation request to the completion of the radiographing preparation, the operability is improved.

When the panel 540 can accumulate electric energy, the cassette control section 530 sends to the console communication section 140 a signal showing that the preparation of the cassette 500 is completed (hereinafter referred to as preparation completion signal). Upon receiving this preparation completion signal, the console communication section 140 transmits to the console control section 130 the preparation completion signal of the cassette 500.

The above processing are shown in FIG. 13 to FIG. 15 as the radiographing preparation processing in Step S200.

When the console control section 130 receives this preparation completion signal of the cassette 500 and receives the X-ray irradiation instruction, the console control section 130 sends an X-ray irradiation signal to the X-ray source 400 (Step S201). Upon receiving the X-ray irradiation signal, the X-ray source control section 430 drives and controls the high voltage generation source 410 to apply a high voltage to the X-ray tube 420, thereby causing the X-ray source 400 to generate an X-ray (Step S221). The X-ray generated by the X-ray source 400 is adjusted with regards to the X-ray emission range by an X-ray aperture apparatus provided in the X-ray irradiation opening, thereby irradiating the subject. The console control section 130 controls the display control section 110 so that the display control section 110 displays that a radiographing is being performed (Step S202).

The X-ray transmitted through the subject incidents into the cassette 500. This X-ray impinged into the cassette 500 is converted by the scintillator 541 to visible light. Then, the converted visible light is received by the panel 540. The electric energy is accumulated according to the amount of the received light. As described above, the electric energy is accumulated by the panel 540 according to the amount of the X-ray irradiation (Step S211).

The amount of X-ray irradiated to the cassette 500 is detected by the X-ray amount sensor 548. When the amount of the X-ray irradiation reaches a predetermined amount, the X-ray amount sensor 548 sends a predetermined X-ray amount signal to the cassette control section 530. When receiving the predetermined X-ray amount signal, the cassette control section 530 sends an X-ray completion signal via the repeater 600 to the console communication section 140 (Step S212). Upon receiving this X-ray completion signal, the console communication section 140 transmits the X-ray completion signal to the console control section 130 and sends an X-ray irradiation stoppage signal to the X-ray source control section 430 (Step S203). When receiving this X-ray irradiation stoppage signal, the X-ray source control section 430 derives and controls the high voltage generation source 410 and the high voltage generation source 410 stops applying the high voltage to the X-ray tube 420. As a result, the generation of X-ray is stopped (Step S222).

When sending the X-ray irradiation completion signal, the cassette control section 530 drives and controls the scanning drive circuit 543 and the signal reading circuit 544 based on the X-ray irradiation completion signal. The scanning drive circuit 543 reads electric energy obtained by the light detector 542 to input the obtained electric energy to the signal reading circuit 544. The signal reading circuit 544 converts the inputted electric energy to a digital signal. Then, the data conversion section 545 composes the digital signal as X-ray image data. The memory 546 temporarily stores the X-ray image data composed by the data conversion section 545 (Step S213).

Next, the cassette control section 530 obtains the X-ray image data to subsequently obtain compensation image data. The compensation image data is dark image data not subjected to an X-ray irradiation that is used to compensate an X-ray image in order to provide the image with a higher quality. The method for obtaining compensation image data is the same as that for obtaining image data except for that X-ray is not irradiated. The period during which electric energy is accumulated is set to be equal when X-ray image data is obtained and when compensation image data is obtained. The “period during which electric energy is accumulated” is a period from the completion of the resetting operation (i.e., turning OFF of the transistor 5425 at the reset) to the next turning ON of the transistor 5425 in order to read electric energy. Thus, a timing at which electric energy accumulation is started or a period during which electric energy is accumulated is different for each scanning line 5422.

Based on the obtained compensation image data, the data conversion section 545 subjects the composed X-ray image data to an offset compensation to subsequently subject the data to a gain compensation based on gain compensation data that is previously obtained and stored in the memory 546. When the panel is the one composed of insensitive pixels or a plurality of small panels, the image is continuously compensated so that the connection between the small panels for example is prevented from being awkward, thereby completing the compensation processing related to the panels (Step S214). Although this embodiment provided the data conversion section 545 and the cassette control section 530 separately, the cassette control section 530 also may work as the data conversion section 545. When the X-ray image data after the compensation processing is temporarily stored in the memory 546, the cassette control section 530 works as a scintillator image information adding section to add a scintillator ID to-the X-ray image data (Step S215), thereby sending the X-ray image data (including the scintillator ID) to the console control section 130 via the cassette communication section 520, the repeater 600, and the console communication section 140 (Step S216).

As described above, this cassette 500 includes the memory 546 that operates by being supplied with power from the internal power source 510 and temporarily stores the X-ray image data that is obtained by the panel 540 and that is sent from the cassette communication section 520. Therefore, the cassette 500 can function as an accumulator between the data generation from the panel 540 and the communication between the cassette 500 and the console 100, thus allowing the X-ray image data to be transferred from the cassette 500 to the console 100 depending on the communication status between the cassette 500 and the console 100. The memory 546 as a RAM allows the data to be stored in a favorable manner, even when the data is generated from the panel 540 with a high speed.

When receiving the X-ray image data (Step S205), the console control section 130 temporarily stores the data in the image storage section 160. Then, the console control section 130 provides a control so that the image processing section 150 generates thumbnail image data based on the X-ray image data temporarily stored in the image storage section 160. Based on the prepared thumbnail image data, the display control section 110 controls the display section 300 to display the thumbnail image (Step S205).

When receiving the X-ray image data including a scintillator ID, the console control section 130 identifies the scintillator ID based on the X-ray image data (Step S206) to specify, based on the scintillator ID, an image processing method depending on the scintillator 541 based on the first data table (see FIG. 4) (Step S207). Then, the console control section 130 causes the image processing section 150 to subject the X-ray image data to an image processing based on the specified image processing method (Step S208). Specifically, the console 100 also works as the image processing apparatus of the present invention.

The image processing section 150 subjects the X-ray image data to an image processing based on the instruction contents from the operator or the order information from the HIS/RIS710 or the like and according to the image processing method specified by the console control section 130. This X-ray image data after the image processing is displayed on the display section 300 while simultaneously being sent to the image storage section 160, thereby being stored as X-ray image data. Furthermore, based on the instruction from the operator, the image processing section 150 subjects the X-ray image data to an image processing again and the result of the image processing of the X-ray image data is displayed by the display section 300 (Step S209).

The network communication section 180 transfers the X-ray image data to external apparatuses on the network such as the imager 720, the image processing terminal 730, the viewer 740, and the file server 750 (Step S210). When the X-ray image data is transferred from the console 100 to an external apparatus, the external apparatus functions to provide a corresponding operation. Specifically, the imager 720 records this X-ray image data on an image recording medium such as a film. The image processing terminal 730 performs an image processing of this X-ray image data or a processing for CAD (Computer Aided Diagnosis) to store the data in the file server 750. The viewer 740 displays an X-ray image based on this X-ray image data. The file server 750 stores this X-ray image data.

As described above, the console control section 130 can provide a control using the power supply status information that shows the status of the power supply to the cassette 500. Thus, a favorable radiographing can be controlled and the radiographing efficiency can be improved. The display section 300 can provide a display depending on the information regarding the power supply status information. Thus, an operator can determine whether the cassette 500 can immediately perform a radiographing or not so that a radiographing operation by another cassette or modality can be prioritized or postponed for example, thereby improving the radiographing efficiency.

As in the description in Embodiment 1, the radiography system 1000 as described above allows the cassette 5 to add a scintillator ID to the X-ray image data so that the console 100 subjects the X-ray image data to an image processing in accordance with the image processing method based on the added scintillator ID and based on the first data table. Thus, the X-ray image data is subjected to an image processing having optimal processing contents depending on the type of the scintillator 541. As a result, the X-ray image can be subjected to an appropriate image processing depending on the type of the scintillator 541.

It is noted that the present invention is not limited to Embodiments 1 to 3 as described above and various modifications and design changes may be provided within the gist of the present invention.

One improvement or design change may be the one in which, in Embodiment 3, as in Embodiment 2, the cassette control section 530 stores a “model ID” unique to the model of the cassette 5 and the console control section 130 stores the second data table (see FIG. 8) so that, when the radiography system 1000 is activated, the cassette control section 530 works as a scintillator information adding-section to add the model ID to the X-ray image data and the console control section 130 identifies the model ID based on the X-ray image data to use the second data table (see FIG. 8), thereby specifying, based on the model ID, an image processing method depending on the type of the scintillator 541.

Another improvement or design change may be the one in which, although Embodiments 1 to 3 showed one-to-one correspondence between the image processing method previously stored in the control section 35 of the console 3 and the console control section 130 of the console 100 and the type of the scintillator 14 or 541, one type of scintillator 14 or 541 also may correspond to a plurality of image processing methods so that a plurality of image processing methods are previously stored, for each type of the scintillator 14 or 541, in the control section 35 and the console control section 130.

In this case, when the control section 35 and the console control section 130 identify a scintillator ID or a model ID based on the image information or the X-ray image data, the control section 35 and the console control section 130 may automatically specify an image processing method having optimal conditions from among a plurality of image processing methods or the control section 35 and the console control section 130 also may cause the display 32 or the display section 300 to display a plurality of image processing methods so that a user (operator) operates the keyboard/mouse 33 or the operation input section 200 to specify an image processing method.

Still another improvement or design change may be the one in which, although Embodiments 1 to 3 described the example with reference to FIG. 4 and FIG. 8 in which the respective processing contents of the gradation processing and the oblique compensation processing are specified as an image processing method corresponding to the scintillator ID and model ID, processing contents with regards to any one of the gradation processing and the oblique compensation processing also may be specified or, in addition to these processing or other than these processing, other processing contents also may be specified, including a frequency enhancement processing, a compensation processing, an expansion/compression processing, a space filtering processing, a recursive processing, a scattering radiation compensation processing, a grid compensation processing, or a dynamic range (DR) compression processing.

Another improvement or design change may be the one in which, in Embodiment 1, not the console 3 but the control apparatus 18 of the radiographic detector 10 stores therein the first data table and the control apparatus 18 of the radiographic detector 10 uses the first data table (see FIG. 4) based on the scintillator ID of the scintillator 14 of the radiographic detector 10 to specify an image processing method depending on the type of the scintillator 14 to add the information of the specified image processing method to the image information. Then, the console 3 subjects, based on the information for the image processing method added to the image information, the image information to an image processing.

Another improvement or design change may be the one in which, in Embodiment 3, not the console 100 but the cassette control section 530 of the cassette 500 stores therein the first data table and the cassette control section 530 of the cassette 500 uses the first data table (see FIG. 4) based on the scintillator ID of the scintillator 541 of the cassette 500 to specify an image processing method depending on the type of the scintillator 541 to add the information for the specified image processing method to the X-ray image data so that the image processing section 150 performs an image processing of the X-ray image data.

Another improvement or design change may be the one in which, in Embodiment 1 to Embodiment 2, an image processing apparatus (not shown) connected to the console 3 is provided and this image processing apparatus stores therein the first data table and the second data table. The image information received from the radiographic detector 10 to the console 3 or image information obtained by processing the information is sent from the console 3 to this image processing apparatus. This image processing apparatus identifies the scintillator ID of the received image information or the model ID of the received image information to identify the scintillator ID based on the identified model ID. Then, based on the scintillator ID, this image processing apparatus uses the first data table (see FIG. 4) to specify an image processing method depending on the type of the scintillator 14 to execute an image processing of the image information by the specified image processing method.

Another improvement or design change may be the one in which, in Embodiment 3, not the console 100 but the imager 720, the image processing terminal 730, the viewer 740, and/or the file server 750 for example connected to the console 100 are/is used to store the first data table and the second data table so that X-ray image data received from the cassette 500 to the console 100 or X-ray image data obtained by processing the data is sent to the imager 720, image processing terminal 730, viewer 740, and/or file server 750 for example. Then, the imager 720, the image processing terminal 730, the viewer 740, and/or the file server 750 for example identify/identifies the scintillator ID of the received X-ray image data or identify/identifies the model ID of the received X-ray image data to identify the scintillator ID based on the identified model ID. Then, based on the scintillator ID, the imager 720, the image processing terminal 730, the viewer 740, and/or the file server 750 for example use/uses the first data table (see FIG. 4) to specify an image processing method depending on the type of the scintillator 541 so that the image processing section 150 executes an image processing of the X-ray image data based on the specified image processing method.

The entire disclosure of a Japanese Patent Application No. 2004-269977, filed on Sep. 16, 2004, including specifications, claims, drawings and summaries are incorporated herein by reference in their entirety.

What is claimed is:

1. A radiography system comprising:
a radiographic detector comprising a scintillator for receiving radiation transmitted through a subject to generate fluorescence, the radiographic detector to generate image information of the subject based on strength of the fluorescence generated by the scintillator; and
a scintillator information adding-section to add scintillator type-related information related to a type of the scintillator, to the image information.

2. The system of claim 1, wherein the scintillator type-related information is scintillator information for specifying the type of the scintillator.

3. The system of claim 1, wherein
the type of the scintillator is specifiable based on a model of the radiographic detector; and
the scintillator type-related information is detector model information depending on the model of the radiographic detector.

4. The system of claim 1, further comprising:
a console comprising a console communication section to communicate with the radiographic detector;
an image processing apparatus which is provided in the console or is connected to the console and which previously stores an image processing method depending on the type of the scintillator;
wherein the radiographic detector comprises a radiographic detector communication section which is communicable with the console;
the generated image information is sent from the radiographic detector communication section to the console;
the console communication section of the console receives the image information sent from the radiographic detector; and
the image processing apparatus obtains the scintillator type-related information added to the image information received by the console, and processes the image information received by the console, in accordance with the image processing method depending on the obtained scintillator type-related information.

5. The system of claim 4, wherein the console also works as the image processing apparatus.

6. The system of claim 4, wherein:
the radiographic detector communication section is communicable with the console via wireless communication; and
the console communication section is communicable with the radiographic detector via wireless communication.

7. The system of claim 6, further comprising a repeater which is communicable with the radiographic detector communication section via wireless communication;
wherein the console communication section is communicable with the repeater via a communication cable.

8. The system of claim 6, further comprising a repeater which is communicable with the radiographic detector communication section via wireless communication;
wherein the console communication section is a mobile terminal which is communicable with the repeater via wireless communication.

9. The system of claim 1, wherein the radiographic detector comprises a memory to store temporarily the image information.

10. The system of claim 4, wherein the radiographic detector is a cable less transportable cassette comprising an internal power source for supplying power for a communication of the communication section of the radiographic detector and to generate the image information.
